(19) United States
(12) Patent Application Publication
(10) Pub. No.: US 2026/0293757 A1
(43) Pub. Date: Sep. 24, 2026

(54) METHOD FOR MANUFACTURING SEMICONDUCTOR DEVICE

(71) Applicant: Resonac Corporation, Minato-ku, Tokyo (JP)

(72) Inventors: Chiharu KOGA, Tokyo (JP); Tomoaki SHIBATA, Tokyo (JP); Seiji KAI, Tokyo (JP)

(21) Appl. No.: 19/477,782

(22) PCT Filed: Dec. 7, 2023
(86) PCT No.: PCT/JP2023/043912

§ 371 Date: Oct. 23, 2025

(51) Int. Cl. H10W 80/00; H10W 72/90; H10W 90/00; H10W 90/10; H10W 90/20

(52) U.S. Cl. CPC H10W 80/327; H10W 72/924; H10W 72/934; H10W 72/953; H10W 80/041; H10W 80/312; H10W 90/10; H10W 90/284; H10W 90/794

(57) ABSTRACT

Hybrid bonding in Chip on Wafer (CoW) which is a three-dimensional integration technology of semiconductors is disclosed. In this method, an organic insulation material M is applied so as to cover redistribution wiring on substrate bodies 101 and 201 to form organic insulation layers 102 and 202. A semiconductor wafer 100 is heated to set the curing rate of the organic insulation layer 102 to 30% or more. The curing rate of the semiconductor wafer 200 is suppressed to 85% or less. The cured semiconductor wafer 100 is singulated to obtain a semiconductor chip 10. The semiconductor chip 10 is mounted on the semiconductor wafer 200 by a chip bonder CB. A bonded body S is reheated to fully cure the organic insulation layer. In this manufacturing method, shear strength can be increased in the hybrid bonding using the organic insulation layer.

### TECHNICAL FIELD

The present disclosure relates to a method for manufacturing a semiconductor device.

### BACKGROUND ART

In recent years, a three-dimensional integration technology has been studied in order to improve the degree of integration of LSIs. Non Patent Literature 1 discloses an example of a technology for three-dimensional integration of semiconductor chips.

### CITATION LIST

### Non Patent Literature

Non Patent Literature 1: F. C. Chen et al., “System on Integrated Chips (SoIC™) for 3D Heterogeneous Integration”, 2019 IEEE 69th Electronic Components and Technology Conference (ECTC), p. 594-599 (2019)

### SUMMARY OF INVENTION

### Technical Problem

As a three-dimensional integration technology of a semiconductor, the use of hybrid bonding has been studied for Wafer-to-Wafer (W2W) bonding or Chip-on-Wafer (CoW) bonding. In the hybrid bonding, as a countermeasure against foreign matter, an organic insulation material may be used for an insulation layer on a connection surface. It is desired to increase bonding strength between such organic insulation layers.

An object of the present disclosure is to provide a method for manufacturing a semiconductor device capable of increasing bonding strength between organic insulation layers.

### Solution to Problem

[1] The present disclosure relates to, as one aspect, a method for manufacturing a semiconductor device. The method for manufacturing this semiconductor device includes: preparing a first semiconductor substrate including a first substrate body, a first organic insulation layer provided on a surface of the first substrate body, and at least one first electrode provided on the surface of the first substrate body; preparing a second semiconductor substrate including a second substrate body, a second organic insulation layer provided on a surface of the second substrate body, and at least one second electrode provided on the surface of the second substrate body; heating at least one of the first semiconductor substrate and the second semiconductor substrate to cure at least one of the first organic insulation layer and the second organic insulation layer by heating; and bonding the first organic insulation layer and the second organic insulation layer to each other and bonding the first electrode and the second electrode to each other, after the heating. The first organic insulation layer and the second organic insulation layer contain a curable resin and a thermal crosslinking agent. In the method for manufacturing this semiconductor device, after the heating, a curing rate of the first organic insulation layer to be subjected to the bonding is equal to or more than 30%, and after the heating, a curing rate of the second organic insulation layer to be subjected to the bonding is equal to or less than 85%.

In the method for manufacturing this semiconductor device, the curing rate of the first organic insulation layer to be subjected to the bonding is equal to or more than 30%, and the curing rate of the second organic insulation layer to be subjected to the bonding is suppressed equal to or less than 85%. Thus, according to the study of the present inventors, it has been found that the bonding strength between the first organic insulation layer and the second organic insulation layer can be increased. As an example, when the first organic insulation layer and the second organic insulation layer are bonded to each other, the shear strength between the organic insulation layers can be set to 5 MPa or more required for hybrid bonding by setting the curing rate of the first organic insulation layer to 30% or more and setting the curing rate of the second organic insulation layer to 85% or less.
[2] In the method for manufacturing a semiconductor device according to [1], the first semiconductor substrate is preferably a semiconductor chip, and the second semiconductor substrate is preferably a semiconductor wafer. In this case, in the heating, the first semiconductor substrate may be heated as a part of a large-sized semiconductor wafer, and after the heating and before the bonding, the large-sized semiconductor wafer may be singulated to form the semiconductor chip. In the bonding, the first semiconductor substrate which is the semiconductor chip is bonded to the second semiconductor substrate which is the semiconductor wafer. In the method for manufacturing this semiconductor device, the bonding strength can be easily increased in the production of a semiconductor device in a Chip-on-Wafer (CoW) form in which one or more singulated semiconductor chips are mounted on a semiconductor wafer.
[3] In the method for manufacturing a semiconductor device according to [1] or [2], in the heating, the first semiconductor substrate is preferably heated such that the curing rate of the first organic insulation layer becomes equal to or more than 70%. In this case, it is possible to suppress occurrence of lateral displacement when the organic insulation layers are bonded to each other. Furthermore, in a case where the first semiconductor substrate is singulated into semiconductor chips, with such a curing rate, it is possible to prevent delamination of portions of the organic insulation layers when the large-sized semiconductor wafer is singulated by dicing.
[4] In the method for manufacturing a semiconductor device according to [1] or [2], in the heating, the first semiconductor substrate is preferably heated such that the curing rate of the first organic insulation layer becomes equal to or more than 90%. In this case, it is possible to suppress occurrence of lateral displacement when the organic insulation layers are bonded to each other. Furthermore, in this case, when the first semiconductor substrate is singulated into semiconductor chips, with such a curing rate, it is possible to more reliably prevent delamination of portions of the organic insulation layers when the large-sized semiconductor wafer is singulated by dicing. Moreover, in this case, when the curing rate of the second organic insulation layer is equal to or less than 10% (including the curing rate of 0% in the uncured state), the bonding strength between the organic insulation layers can be further increased, and as an example, the shear strength between the organic insulation layers can be set to 20 MPa or more.
[5] In the method for manufacturing a semiconductor device according to any one of [1] to [4], in the heating, the second semiconductor substrate may be heated such that the curing rate of the second organic insulation layer becomes equal to or less than 60%. In this case, by suppressing the curing rate of the second organic insulation layer that receives the first organic insulation layer to 60% or less, the bonding strength between the organic insulation layers can be increased.
[6] In the method for manufacturing a semiconductor device according to any one of [1] to [5], the curing rate of the second organic insulation layer may be equal to or less than 10% when the first organic insulation layer and the second organic insulation layer are bonded to each other. In this case, by suppressing the curing rate of the second organic insulation layer that receives the first organic insulation layer to 10% or less, the bonding strength between the organic insulation layers can be further increased.
[7] In the method for manufacturing a semiconductor device according to [6], when the first organic insulation layer and the second organic insulation layer are bonded to each other, the second organic insulation layer is preferably in an uncured state. In this case, since the second organic insulation layer that receives the first organic insulation layer is not cured, the bonding strength between the organic insulation layers can be further increased.
[8] The method for manufacturing a semiconductor device according to any one of [1] to [7] preferably further includes reheating a bonded body of the first semiconductor substrate and the second semiconductor substrate after the bonding. The reheating temperature in the reheating the bonded body is preferably higher than the heating temperature in the heating at least one of the first semiconductor substrate and the second semiconductor substrate. In this case, the organic insulation layer is further cured by reheating at a high temperature after bonding, and the bonding between the organic insulation layers can be strengthened.
[9] In the method for manufacturing a semiconductor device according to any one of [1] to [8], the first organic insulation layer and the second organic insulation layer may contain a photosensitive resin composition. The photosensitive resin composition may contain the curable resin. Since each organic insulation layer is formed of the photosensitive resin composition, in the electrode integration, production by means of a damascene process is enabled. Furthermore, in this case, since the same materials as those used in the steps of redistribution wiring and passivation that have already been put into practical use can be used, it is easy to put to practical use.
[10] In the method for manufacturing a semiconductor device according to [9], the photosensitive resin composition preferably contains an alkali-soluble resin having a phenolic hydroxyl group, a compound that generates acid upon exposure to light, a thermal crosslinking agent, and an acrylic resin. In this case, the photosensitive resin composition can be cured at a low temperature, and the curing rate of the organic insulation layer can be efficiently increased. Furthermore, since adhesion can be improved and good thermal shock resistance can be obtained, the function as an insulation layer can be improved.
[11] In the method for manufacturing a semiconductor device according to any one of [1] to [9], the first organic insulation layer and the second organic insulation layer may contain a polyimide resin. In this case, a semiconductor device having excellent heat resistance can be produced.
[12] In the method for manufacturing a semiconductor device according to any one of [1] to [11], the first organic insulation layer and the second organic insulation layer may be formed of the same type of resin material, and the heating at least one of the first semiconductor substrate and the second semiconductor substrate may include heating the first semiconductor substrate at a first temperature and heating the second semiconductor substrate at a second temperature, the first temperature being higher than the second temperature. In this case, the curing rates of the first organic insulation layer and the second organic insulation layer can be easily set to desired values.

### Advantageous Effects of Invention

According to the present disclosure, it is possible to provide a method for manufacturing a semiconductor device capable of increasing the bonding strength between the organic insulation layers.

### BRIEF DESCRIPTION OF DRAWINGS

FIG. 1 is a perspective view schematically illustrating an example of a semiconductor device manufactured by a method for manufacturing a semiconductor device according to an embodiment of the present disclosure.

FIG. 2 (a) to (e) of FIG. 2 are schematic views sequentially illustrating a method for manufacturing the semiconductor device illustrated in FIG. 1.

FIG. 3 (a) to (d) of FIG. 3 are schematic cross-sectional views sequentially illustrating a method for manufacturing the semiconductor device illustrated in FIG. 1.

FIG. 4 (a) and (b) of FIG. 4 are schematic cross-sectional views illustrating a method for manufacturing the semiconductor device illustrated in FIG. 1.

FIG. 5 is a schematic cross-sectional view illustrating a method for measuring bonding strength (shear strength) between organic insulation layers.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description is omitted. Furthermore, unless otherwise specified, positional relationships such as up, down, left, and right are based on the positional relationships illustrated in the drawings. The use of the terms “left”, “right”, “front”, “back”, “up”, “down”, “above”, “below”, and the like in the description and claims of this specification is intended for description and is not necessarily meant to indicate a permanent relative position thereof. Moreover, dimensional ratios in the drawings are not limited to the illustrated ratios.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved. A numerical range using “to” indicates a range including numerical values described before and after “to” as a minimum value and a maximum value.

### (Configuration of Semiconductor Device)

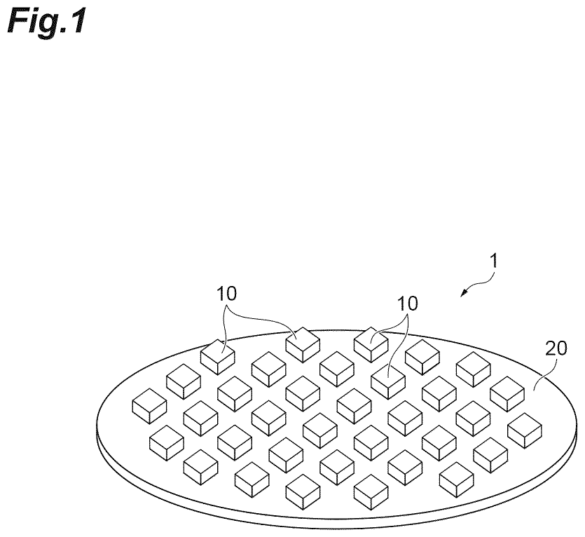

FIG. 1 is a perspective view schematically illustrating an example of a semiconductor device manufactured by a method for manufacturing a semiconductor device according to the present embodiment. As illustrated in FIG. 1, a semiconductor device 1 is, for example, an example of a semiconductor package, includes a plurality of semiconductor chips 10 (first semiconductor substrate) and a semiconductor wafer 20 (second semiconductor substrate), and has a Chip-on-Wafer (CoW) structure. The plurality of semiconductor chips 10 are produced by singulating a first semiconductor substrate 100 to be described later into individual pieces by dicing. The plurality of semiconductor chips 10 are mounted on the semiconductor wafer 20 to form a three-dimensional mounting structure. The semiconductor wafer 20 may be a substrate in which a plurality of semiconductor chips such as a large scale integrated circuit (LSI) chip or a complementary metal oxide semiconductor (CMOS) sensor are formed at places corresponding to the respective semiconductor chips 10. Each of the semiconductor chips 10 may be, for example, a semiconductor chip such as an LSI or a memory. The plurality of semiconductor chips 10 and the semiconductor wafer 20 are finely bonded to each other by hybrid bonding to be described later such that terminal electrodes and the organic insulation layers around the terminal electrodes are firmly bonded and positioned without positional misalignment. The semiconductor device 1 may be further singulated into individual semiconductor devices including one semiconductor chip 10 further singulated from the configuration illustrated in FIG. 1 and a substrate portion which is a part of the semiconductor wafer 20 corresponding to one semiconductor chip 10.

### (Method for Manufacturing Semiconductor Device)

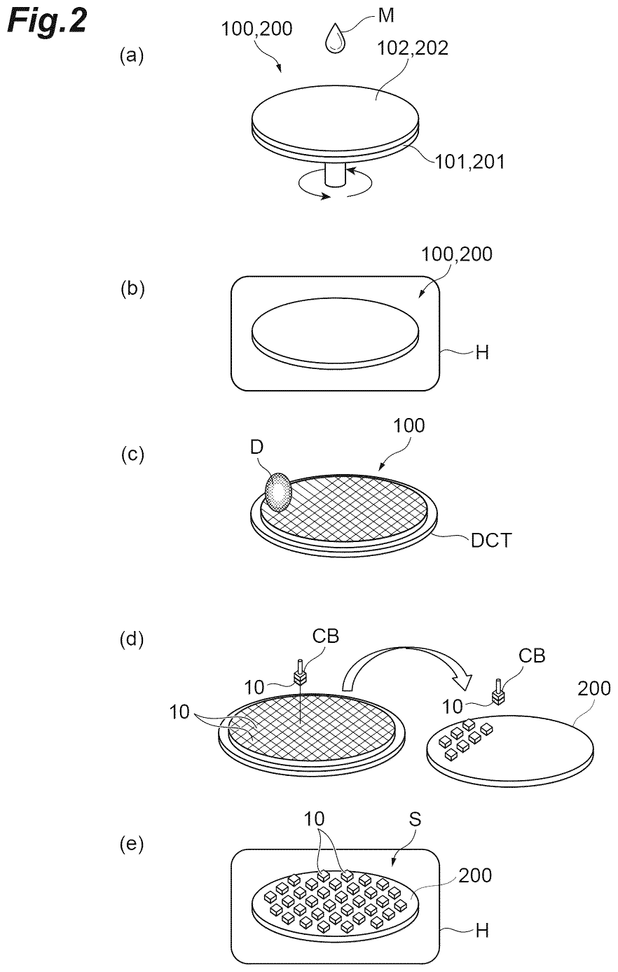

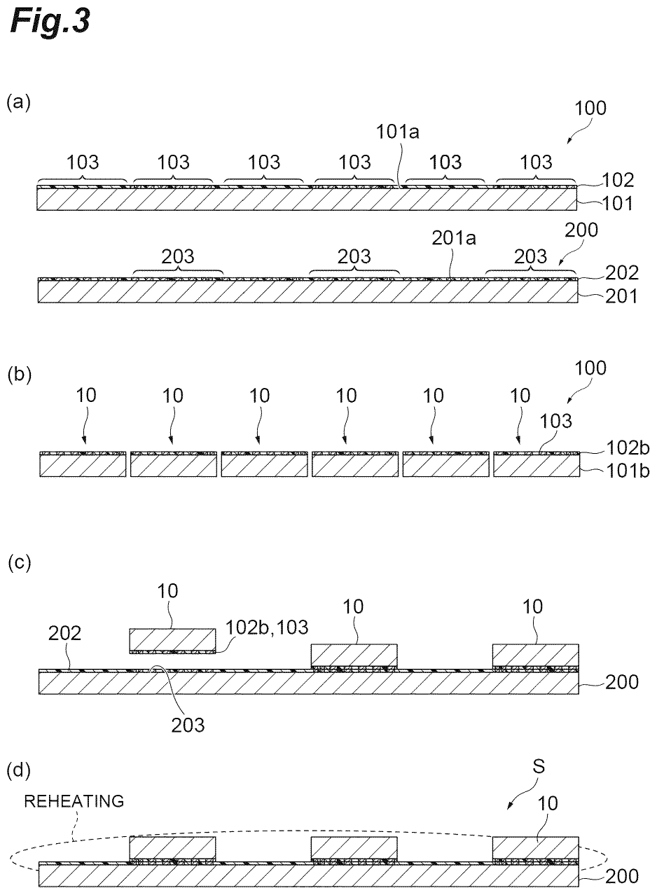

Next, a method for manufacturing the semiconductor device 1 will be described with reference to FIGS. 2 and 3. (a) to (e) of FIG. 2 and (a) to (d) of FIG. 3 are schematic views sequentially illustrating a method for manufacturing the semiconductor device 1 illustrated in FIG. 1.

The semiconductor device 1 can be manufactured, for example, through the following steps (a) to (f).
(a) A step of preparing a first semiconductor substrate including a first substrate body, and a first organic insulation layer provided on a surface of the first substrate body, and at least one first electrode provided on the surface of the first substrate body.
(b) A step of preparing a second semiconductor substrate including a second substrate body, and a second organic insulation layer provided on a surface of the second substrate body, and at least one second electrode provided on the surface of the second substrate body.
(c) A step of heating at least one of the first semiconductor substrate and the second semiconductor substrate to cure at least one of a first organic insulation layer and a second organic insulation layer by heating.
(d) A step of singulating the large-sized first semiconductor substrate after the heating step of step (c) and before the bonding step of step (e).
(e) A step of bonding the first organic insulation layer and the second organic insulation layer to each other and bonding the first electrode and the second electrode to each other, after the heating step.
(f) A step of reheating the bonded body of the first semiconductor substrate (semiconductor chip after singulation) and the second semiconductor substrate, after the bonding step (e).
   [Step (a)]

Step (a) is a step of preparing a first semiconductor substrate 100 which is a silicon substrate on which an integrated circuit including semiconductor elements and wiring connecting the semiconductor elements is formed. The first semiconductor substrate 100 corresponds to the semiconductor chips 10 of the semiconductor device 1 illustrated in FIG. 1. In step (a), as illustrated in (a) of FIG. 2, a liquid organic insulation material M is applied to a surface of a substrate body 101 (first substrate body) made of silicon or the like, on which redistribution wiring has been provided, and then spin coating is performed. Thereafter, a light heat treatment is performed on the applied organic insulation material to volatilize the solvent in the application solution and form a film. Thus, as illustrated in (a) of FIG. 3, the first semiconductor substrate 100 including the substrate body 101, an organic insulation layer 102 (first organic insulation layer) provided on a surface 101a of the substrate body 101, and a redistribution wiring portion 103 (first electrode) provided on the surface 101a of the substrate body 101, is prepared. A redistribution wiring layer (RDL layer) is formed of the organic insulation layer 102 and the redistribution wiring portions 103. Each redistribution wiring portion 103 is formed to include a plurality of terminal electrodes and wiring formed of copper, aluminum, or the like, and is provided at predetermined intervals. The redistribution wiring portion 103 is configured to expose an integrated circuit or the like formed on the first semiconductor substrate 100 to the outside through the organic insulation layer 102. The thickness of the organic insulation layer 102 may be, for example, from 1 μm to 10 μm, or may be equal to or less than 5 μm. Note that in the above description, the method for providing the redistribution wiring portion 103 on the substrate body 101 and then providing the organic insulation layer 102 has been described, but the present disclosure is not limited thereto, and the redistribution wiring portion 103 may be provided after providing the organic insulation layer 102.

[Step (b)]

Step (b) is a step similar to step (a), and is a step of preparing a second semiconductor substrate 200 which is a silicon substrate on which an integrated circuit including semiconductor elements and wiring that connects the semiconductor elements is formed. The second semiconductor substrate 200 corresponds to the semiconductor wafer 20 of the semiconductor device 1 illustrated in FIG. 1. In step (b), as illustrated in (a) of FIG. 2 and (a) of FIG. 3, a liquid organic insulation material is applied to a surface of a substrate body 201 (second substrate body) made of silicon or the like, on which redistribution wiring has been provided, and then spin coating is performed. Thereafter, a light heat treatment is performed on the applied organic insulation material to volatilize the solvent in the application solution and form a film. Thus, as illustrated in (a) of FIG. 3, the second semiconductor substrate 200 including the substrate body 201, an organic insulation layer 202 (second organic insulation layer) provided on a surface 201a of the substrate body 201, and a redistribution wiring portion 203 (second electrode) provided on the surface 201a of the substrate body 201, is prepared. A redistribution wiring layer (RDL layer) is formed of the organic insulation layer 202 and the redistribution wiring portions 203. Each redistribution wiring portion 203 is formed to include a plurality of terminal electrodes and wiring formed of copper, aluminum, or the like, and is provided at predetermined intervals. The redistribution wiring portion 203 is configured to expose an integrated circuit or the like formed on the second semiconductor substrate 200 to the outside through the organic insulation layer 202. The thickness of the organic insulation layer 202 may be, for example, from 1 μm to 10 μm, or may be equal to or less than 5 μm. Note that in the above description, the method for providing the redistribution wiring portion 203 on the substrate body 201 and then providing the organic insulation layer 202 has been described, but the present disclosure is not limited thereto, and the redistribution wiring portion 203 may be provided after providing the organic insulation layer 202. The organic insulation material forming the organic insulation layer 202 may be the same kind of material as the organic insulation material forming the organic insulation layer 102 described above, or may be other organic insulation materials.

In steps (a) and (b), polishing may be performed to planarize the surfaces of the organic insulation layers 102 and 202 and the redistribution wiring portions 103 and 203. The surface roughness Ra of the organic insulation layers 102 and 202 and the redistribution wiring portions 103 and 203 after polishing may be equal to or less than 1 nm. Furthermore, this polishing treatment may be performed after the heating step in step (c) to be described later in detail.

The resin composition forming the organic insulation material M used to form the organic insulation layers 102 and 202 in steps (a) and (b) is not particularly limited, but may contain a curable resin, or may contain a photosensitive resin composition. Such a photosensitive resin composition may contain, for example, (A) an alkali-soluble resin having a phenolic hydroxyl group, (B) a compound that generates acid upon exposure to light, (C) a thermal crosslinking agent, and (D) an acrylic resin.

### <Component (A)>

A component (A): an alkali-soluble resin having a phenolic hydroxyl group

The component (A) is a resin having a phenolic hydroxyl group in its molecule and soluble in an alkaline developer. Examples of the alkali-soluble resin having a phenolic hydroxyl group as the component (A) include a hydroxystyrene-based resin such as polyhydroxystyrene or a copolymer containing hydroxystyrene as a monomer unit, a phenolic resin, a polybenzoxazole precursor such as poly(hydroxyamide), poly(hydroxyphenylene) ether, and polynaphthol. The component (A) may be composed of only one of these resins, or may be composed of two or more thereof.

Among them, the component (A) is preferably a phenolic resin, and particularly preferably a novolac-type phenolic resin, due to its low price, high contrast, and small volume shrinkage during curing. Furthermore, the component (A) may be a hydroxystyrene-based resin since it is excellent in electrical properties (insulation) and has small volume shrinkage during curing.

The phenolic resin is a polycondensation product of phenol or a derivative thereof and aldehydes. The polycondensation is performed in the presence of a catalyst such as an acid or a base. The phenolic resin obtained in a case where an acid catalyst is used is particularly referred to as a novolac-type phenolic resin. Specific examples of the novolac resin include phenol/formaldehyde novolac resin, cresol/formaldehyde novolac resin, xylenol/formaldehyde novolac resin, resorcinol/formaldehyde novolac resin, and phenol-naphthol/formaldehyde novolac resin.

### <Component (B)>

A compound that generates acid upon exposure to light, which is a component (B), is used as a photosensitizer. Such a component (B) has a function of generating an acid by light irradiation and increasing the solubility of the light-irradiated portion in an alkaline aqueous solution.

As the component (B), a compound generally referred to as a photoacid generator can be used. Specific examples of the component (B) include an o-quinonediazide compound, an aryl diazonium salt, a diaryliodonium salt, and a triarylsulfonium salt. Among them, the o-quinonediazide compound is preferably used as the component (B) due to high sensitivity.

The mixing amount of the component (B) is preferably 3 to 100 parts by mass, more preferably 5 to 50 parts by mass, and particularly preferably 5 to 30 parts by mass with respect to 100 parts by mass of the component (A) from the viewpoint of a difference in dissolution rate between an exposed portion and an unexposed portion and the allowable range of sensitivity.

### <Component (C)>

By containing the thermal crosslinking agent as a component (C), when curing the applied photosensitive resin layer by heating, the component (C) reacts with the component (A) to form a crosslinked structure. This enables curing at a low temperature, and brittleness of the insulation layer and melting of the insulation layer can be prevented. Specifically, as the component (C), a compound having a phenolic hydroxyl group, a compound having a hydroxymethylamino group, or a compound having an epoxy group can be used as preferable components.

Note that the “compound having a phenolic hydroxyl group” as referred to herein does not contain the alkali-soluble resin having a phenolic hydroxyl group (A). The compound having a phenolic hydroxyl group as a thermal crosslinking agent can increase the dissolution rate of the exposed portion at the time of development with an alkaline aqueous solution as well as the thermal crosslinking agent, and can improve the sensitivity. The molecular weight of such a compound having a phenolic hydroxyl group is preferably equal to or less than 2000. The number average molecular weight is preferably from 94 to 2000, more preferably from 108 to 2000, and particularly preferably from 108 to 1500 in consideration of solubility in an alkaline aqueous solution and the balance between photosensitive properties and mechanical properties. Note that as the compound having a phenolic hydroxyl group, conventionally known compounds can be used.

### <Component (D)>

By containing the acrylic resin as a component (D), it is possible to improve thermal shock resistance while maintaining good photosensitive properties. The acrylic resin is preferably an acrylic resin having one or two or more structural units represented by the following general formulas (1) to (3).

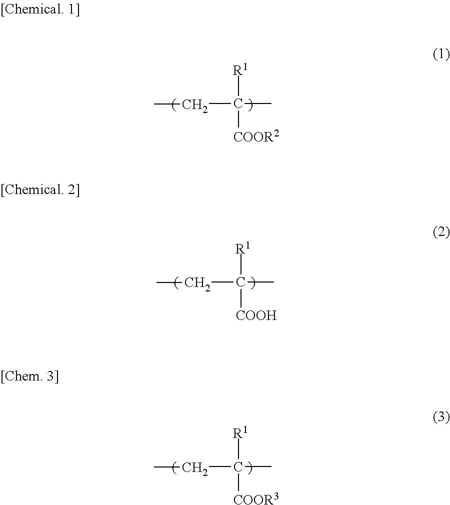

[In the general formulas (1) to (3), R¹ represents a hydrogen atom or a methyl group, R² represents an alkyl group having 4 to 20 carbon atoms, and R³ represents a monovalent organic group having a primary, secondary, or tertiary amino group.]

In particular, by containing an acrylic resin having a structural unit represented by the general formula (1) and a structural unit represented by the general formula (2), thermal shock resistance can be improved while maintaining good photosensitive properties. Furthermore, from the viewpoint of further improving compatibility with the component (A), adhesion of the organic insulation layer to the substrate, mechanical properties, and thermal shock resistance, it is more preferable to contain an acrylic resin having a structural unit represented by the general formula (1), a structural unit represented by the general formula (2), and a structural unit represented by the general formula (3). The component (D) may be formed of only one kind of the acrylic resin, or may contain two or more kinds thereof.

The mixing amount of the component (D) is preferably 1 to 50 parts by mass, more preferably 3 to 30 parts by mass, and particularly preferably 5 to 20 parts by mass with respect to 100 parts by mass of the total amount of the component (A) from the viewpoint of adhesion, mechanical properties, thermal shock resistance, and photosensitive properties.

The photosensitive resin composition described above may contain, as other components, components such as a compound that generates acid upon heating, an elastomer, a dissolution promoter, a dissolution inhibitor, a coupling agent, and a surfactant or a leveling agent. Specific examples of the compound that generates acid upon heating include a compound different from the compound of the component (B) that generates acid upon exposure to light, such as a salt formed of a strong acid and a base such as an onium salt having a function of generating acid upon heating, or an imidosulfonate. As the elastomer, a conventionally known elastomer can be used, but the glass transition temperature (Tg) of a polymer forming the elastomer is preferably equal to or less than 20° C. Examples of the elastomer include a styrene-based elastomer, an olefin-based elastomer, a urethane-based elastomer, a polyester-based elastomer, a polyamide-based elastomer, and a silicone-based elastomer.

Furthermore, a solvent can be used for the photosensitive resin composition described above. Since the photosensitive resin composition contains a solvent, the photosensitive resin composition provides the effect of facilitating application onto a substrate and forming a coating film of uniform thickness. Examples of the solvents include γ-butyrolactone, ethyl lactate, propylene glycol monomethyl ether acetate, benzyl acetate, n-butyl acetate, ethoxyethyl propionate, 3-methyl methoxypropionate, N-methyl-2-pyrrolidone, N,N-dimethylformamide, N,N-dimethylacetamide, dimethyl sulfoxide, hexamethylphosphorylamide, tetramethylene sulfone, diethyl ketone, diisobutyl ketone, methyl amyl ketone, cyclohexanone, propylene glycol monomethyl ether, propylene glycol monopropyl ether, propylene glycol monobutyl ether, and dipropylene glycol monomethyl ether. These solvents can be used singly or in combination of two or more kinds thereof. The content in a case where a solvent is used is not particularly limited, but is preferably adjusted such that the proportion of the solvent in the photosensitive resin composition is from 20 mass % to 90 mass %.

In steps (a) and (b), in a case where the organic insulation material M formed of the above-described photosensitive resin composition is applied to form an organic insulation layer, predetermined patterning may be formed by exposure with a semiconductor laser or the like that emits light of a predetermined wavelength.

The organic insulation material used for the organic insulation layers 102 and 202 in step (a) and step (b) is not limited to the photosensitive resin composition described above, and may contain, for example, a polyimide resin, a polyimide precursor (for example, polyimide amic ester or polyamic acid), a polyamide-imide resin, a bismaleimide resin, a benzocyclobutene (BCB) resin, a polybenzoxazole (PBO) resin, or a PBO precursor.

The organic insulation layers 102 and 202 in step (a) and step (b) are mainly formed of an organic insulation material, but may partially include an inorganic insulation material or an inorganic insulation layer.

[Step (c)]

Subsequently, when the preparation of the first semiconductor substrate 100 and the second semiconductor substrate 200 is completed, as illustrated in (b) of FIG. 2, at least one of the first semiconductor substrate 100 and the second semiconductor substrate 200 is heated, and at least one of the organic insulation layer 102 and the organic insulation layer 202 is cured by heating. By this heat-curing, the curing rate of the organic insulation layer 102 of the first semiconductor substrate 100 becomes equal to or more than 30%, and the curing rate of the organic insulation layer 202 of the second semiconductor substrate 200 becomes equal to or less than 85%. In step (c), each semiconductor substrate is housed in a heating device H and heated to a temperature of 100° C. to 200° C., and by continuing heating for a predetermined time (for example, 30 minutes), a curing treatment is performed.

The “curing rate” as referred to herein can be determined using a Fourier transform infrared spectrophotometer (FT-IR). Specifically, the curing rate can be determined in accordance with the following procedure.
(i) The FT-IR spectrum of the organic insulation layer before the curing treatment in step (c) is measured, and a ratio A_{N1} (=S_{A1}/S_{B1}) of the peak area S_{A1} of a peak attributed to a structure X involved in a curing reaction in a chemical structure of the thermal crosslinking agent to the peak area S_{B1} of a peak attributed to a structure Y not involved in the curing reaction in the chemical structure of the curable resin, is calculated.
(ii) The FT-IR spectrum of the organic insulation layer after the curing treatment in step (c) is measured, and a ratio A_{N2} (=S_{A2}/S_{B2}) of the peak area S_{A2} of the peak attributed to the structure X of the thermal crosslinking agent to the peak area S_{B2} of the peak attributed to the structure Y of the curable resin, is calculated.
(iii) Using A_{N1} and A_{N2} obtained in (i) and (ii), the curing rate is calculated in accordance with the following formula (4).

$$Curing rate ( \% ) = \{ ( {A}_{N 1} - {A}_{N 2} ) / {A}_{N 1} \} \times 100 \qquad ( 4 )$$

For example, in a case where the organic insulation layer contains a compound having a methoxy group at the terminal as the thermal crosslinking agent and an alkali-soluble resin having a phenolic hydroxyl group as the curable resin, the peak areas of peaks at a wavenumber of 1080 cm⁻¹ (peaks attributed to a methoxy group (C—O) of the thermal crosslinking agent) can be used as S_{A1} and S_{A2}, and the peak areas of peaks at 700 cm⁻¹ (peaks attributed to a phenyl group (C—H) of the curable resin) can be used as S_{B1} and S_{B2}.

In step (c), in the heat treatment performed on the first semiconductor substrate 100, which is to be singulated in the subsequent step, the heating may be performed such that the curing rate of the organic insulation layer 102 becomes equal to or more than 50%, the heating may be performed such that the curing rate of the organic insulation layer 102 becomes equal to or more than 70%, or the heating may be performed such that the curing rate of the organic insulation layer 102 becomes equal to or more than 90%. By sufficiently curing the organic insulation layer 102 in the first semiconductor substrate 100 to be singulated, resin delamination during singulation by dicing is prevented. The temperature in the heating step for the first semiconductor substrate 100 may be, for example, from 140° C. to 200° C., or may be higher than the temperature in the heating step for the second semiconductor substrate 200. That is, the organic insulation layer 102 of the first semiconductor substrate 100 may be cured more than the organic insulation layer 202 of the second semiconductor substrate 200. Note that the curing may be enhanced not only by increasing the heating temperature but also by increasing the heating time.

In step (c), in the heating treatment performed on the second semiconductor substrate 200, which is not to be singulated in the subsequent step, the heating may be performed similarly to the heating treatment performed on the first semiconductor substrate 100, but the heating may not be performed. In a case where the second semiconductor substrate 200 is not heated or the heating temperature is low in step (c), the organic insulation layer 202 of the second semiconductor substrate 200 remains in an uncured state. On the other hand, in a case where the second semiconductor substrate 200 is heated, the second semiconductor substrate 200 may be heated such that the curing rate of the organic insulation layer 202 becomes equal to or less than 60%, or the second semiconductor substrate 200 may be heated such that the curing rate of the organic insulation layer 202 becomes equal to or less than 10%. Since the second semiconductor substrate 200 is not singulated in step (d), unlike the organic insulation layer 102 of the first semiconductor substrate 100, the second semiconductor substrate 200 may not be cured so as to have a high curing rate from the beginning. The temperature in the heating step for the second semiconductor substrate 200 may be, for example, from 120° C. to 170° C., or may be lower than the heating temperature of the first semiconductor substrate 100. That is, it is preferable that the organic insulation layer 202 of the second semiconductor substrate 200 is not cured as much as the organic insulation layer 102 of the first semiconductor substrate 100. Note that the curing may be suppressed not only by reducing the heating temperature but also by decreasing the heating time.

[Step (d)]

Step (d) is a step of singulating the large-sized (wafer-like) first semiconductor substrate 100 to obtain a plurality of semiconductor chips 10 (first semiconductor substrates) after the heating step of step (c) and before the bonding step of step (e) to be described later. In step (d), as illustrated in (c) of FIG. 2 and (b) of FIG. 3, the first semiconductor substrate 100 is attached to a dicing tape DCT. Thereafter, the first semiconductor substrate 100 is singulated into a plurality of semiconductor chips 10 by a cutting means such as a dicing blade D (dicer). The stacked structure of the singulated semiconductor chip 10 is same as that of the first semiconductor substrate 100. By step (d), as illustrated in (b) of FIG. 3, the substrate body 101 and the organic insulation layer 102 of the first semiconductor substrate 100 are divided into a substrate body 101b and an organic insulation layer 102b corresponding to each semiconductor chip 10. As a dicing method for singulating the first semiconductor substrate 100, for example, it is preferable to use a dicer including the dicing blade D, but stealth dicing or laser dicing may be used.

[Step (e)]

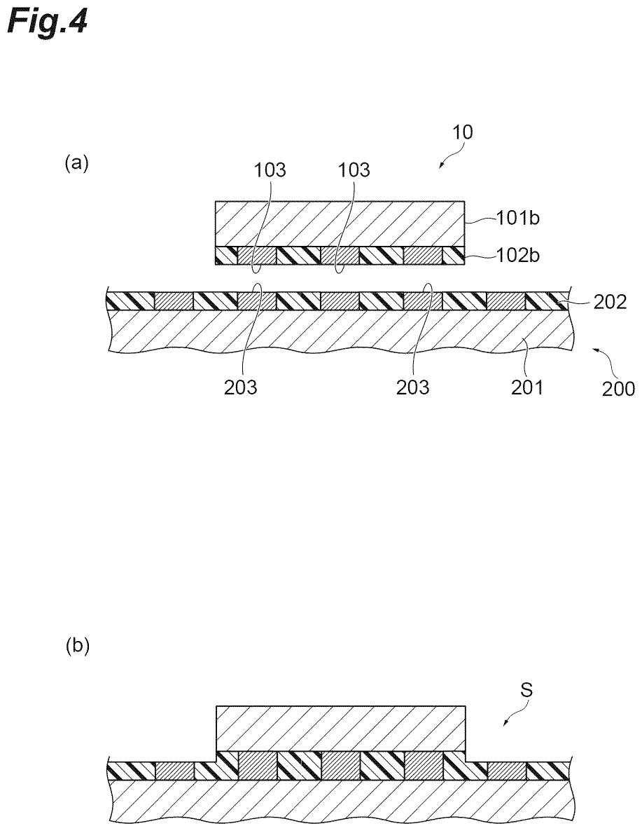

Step (e) is a step of bonding the organic insulation layer 102b and the organic insulation layer 202 to each other and bonding each electrode of the redistribution wiring portion 103 and each electrode of the redistribution wiring portion 203 to each other, after the singulation step of step (d). In step (e), as illustrated in (d) of FIG. 2 and (c) of FIG. 3, the singulated semiconductor chip 10 is picked up by a chip bonder CB, and the semiconductor chip 10 is mounted at a predetermined position on the second semiconductor substrate 200. For example, the chip bonding temperature may be 230° C., the bonding pressure may be 1.5 MPa, and the bonding time may be from 10 seconds to 20 seconds. At the time of this chip bonding, the organic insulation layer 102b and the organic insulation layer 202 face each other, each electrode of the redistribution wiring portion 103 and each electrode of the redistribution wiring portion 203 are aligned, and bonding is performed. In (a) and (b) of FIG. 4, a state in which the semiconductor chip 10 and the second semiconductor substrate 200 are bonded is illustrated in an enlarged manner.

[Step (f)]

Step (f) is a step of reheating the bonded body of the first semiconductor substrate 100 (semiconductor chip 10 after singulation) and the second semiconductor substrate 200 after the bonding step of step (e). In step (f), as illustrated in (e) of FIG. 2 and (d) of FIG. 3, a bonded body S of the semiconductor chips 10 and the second semiconductor substrate 200 bonded by chip bonding in the bonding step of step (e) is disposed in the heating device H, heated to the temperature of 200° C. or higher, and the heating is continued for a predetermined time (for example, 2 hours) to perform heat-curing. Thus, the organic insulation layer 102b of each semiconductor chip 10 corresponding to the first semiconductor substrate 100 and the organic insulation layer 202 of the second semiconductor substrate 200 are fully cured. By the full curing in step (f), the curing rates of the organic insulation layer 102b and the organic insulation layer 202 become, for example, equal to or more than 97%, and become substantially 100%. The curing rate of the organic insulation layer is preferably equal to or more than 97% or substantially 100% by reheating, but the curing rate may not be 100% as long as the bonding strength (shear strength) between the organic insulation layer 102b and the organic insulation layer 202 becomes equal to or more than 5 MPa which is a predetermined value.

By the heating in step (f), the bonding at the bonding portion between the redistribution wiring portion 103 of the semiconductor chip 10 corresponding to the first semiconductor substrate 100 and the redistribution wiring portion 203 of the second semiconductor substrate 200 may be strengthened.

As described above, the semiconductor device 1 illustrated in FIG. 1 is obtained. The semiconductor device 1 may be further singulated to produce a plurality of semiconductor devices.

As described above, in the method for manufacturing a semiconductor device according to the present embodiment, when the organic insulation layers 102b and 202 are bonded to each other, the curing rate of the organic insulation layer 102b is set to 30% or more, and the curing rate of the organic insulation layer 202 is suppressed to 85% or less. Thus, it is possible to increase the bonding strength between the organic insulation layer 102b and the organic insulation layer 202. As an example, when the organic insulation layer 102b and the organic insulation layer 202 are bonded, the shear strength between the organic insulation layers can be set to 5 MPa or more required for hybrid bonding by setting the curing rate of the organic insulation layer 102b to 30% or more and setting the curing rate of the organic insulation layer 202 to 85% or less.

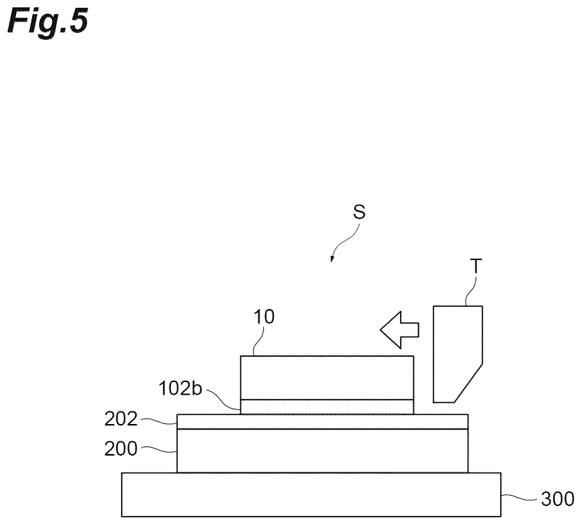

Here, a method for measuring the bonding strength between the semiconductor chip 10 and the second semiconductor substrate 200 will be described with reference to FIG. 5. The bonding strength here means the shear strength. First, the bonded body S including the semiconductor chip 10 and the second semiconductor substrate 200 in which the organic insulation layers are bonded, is prepared on a stage 300. Then, a tool T is moved in the direction of the illustrated arrow from the side of the semiconductor chip 10 of the bonded body S, and the strength when the semiconductor chip 10 is delaminated is measured. The height of the tool T from the upper surface of the second semiconductor substrate 200 is 20 μm, the moving speed of the tool T is 20 μm/s, and the width of the tool T is 5 mm. In the measurement of the shear strength, the shear strength is measured for each specimen (each sample of the bonded body S) with n=5, and the shear strength can be defined as the average of three values obtained by excluding the maximum value and the minimum value.

In the method for manufacturing a semiconductor device according to the present embodiment, the first semiconductor substrate 100 is singulated into semiconductor chips 10, and the second semiconductor substrate 200 is a semiconductor wafer. After the heating step and before the bonding step, the large-sized semiconductor wafer is singulated to form the semiconductor chips 10. In the bonding step, the semiconductor chip 10 is bonded to the second semiconductor substrate 200 which is the semiconductor wafer. In this manufacturing method, the bonding strength can be easily increased in the production of a semiconductor device in a Chip-on-Wafer (CoW) form in which one or more singulated semiconductor chips are mounted on a semiconductor wafer.

In the method for manufacturing a semiconductor device according to the present embodiment, in step (c), the first semiconductor substrate 100 may be heated such that the curing rate of the organic insulation layer 102 becomes equal to or more than 70%. In this case, it is possible to suppress occurrence of lateral displacement when the organic insulation layers are bonded to each other. Furthermore, with such a curing rate, it is possible to prevent delamination of portions of the organic insulation layers 102 and 102b when the large-sized semiconductor wafer is singulated by dicing.

In the method for manufacturing a semiconductor device according to the present embodiment, in step (c), the first semiconductor substrate 100 is preferably heated such that the curing rate of the organic insulation layers 102 and 102b becomes equal to or more than 90%. In this case, it is possible to suppress occurrence of lateral displacement when the organic insulation layers are bonded to each other.

Furthermore, with such a curing rate, it is possible to more reliably prevent delamination of portions of the organic insulation layers 102 and 102b when the large-sized semiconductor wafer is singulated by dicing. Moreover, in this case, when the curing rate of the organic insulation layer 202 on the opposite side is equal to or less than 10% (including the curing rate of 0% in the uncured state), the bonding strength between the organic insulation layers can be further increased, and as an example, the shear strength between the organic insulation layers can be set to 20 MPa or more.

In the method for manufacturing a semiconductor device according to the present embodiment, in step (c), the second semiconductor substrate 200 may be heated such that the curing rate of the organic insulation layer 202 becomes equal to or less than 60%. In this case, by suppressing the curing rate of the organic insulation layer 202 that receives the organic insulation layer 102b to 60% or less, the bonding strength between the organic insulation layers can be increased.

In the method for manufacturing a semiconductor device according to the present embodiment, when the organic insulation layer 102b and the organic insulation layer 202 are bonded to each other, the curing rate of the organic insulation layer 202 may be equal to or less than 10%. In this case, by suppressing the curing rate of the organic insulation layer 202 that receives the organic insulation layer 102b to 10% or less, the bonding strength between the organic insulation layers can be further increased.

In the method for manufacturing a semiconductor device according to the present embodiment, when the organic insulation layer 102b and the organic insulation layer 202 are bonded to each other, the organic insulation layer 202 is preferably in an uncured state. In this case, since the organic insulation layer 202 that receives the organic insulation layer 102b is not cured, the bonding strength between the organic insulation layers can be further increased.

The method for manufacturing a semiconductor device according to the present embodiment further includes a step (f) of reheating the bonded body S of the first semiconductor substrate (semiconductor chip 10) and the second semiconductor substrate 200 after step (d). The reheating temperature in step (f) of reheating the bonded body S is preferably higher than the heating temperature in step (c) of heating at least one of the first semiconductor substrate 100 and the second semiconductor substrate 200. In this case, the organic insulation layer is further cured by reheating at a high temperature after bonding, and the bonding between the organic insulation layers can be strengthened. Furthermore, the electrode material is remelted at the bonding surface between the bonded electrodes, and thus the bonding between the electrodes can be strengthened.

In the method for manufacturing a semiconductor device according to the present embodiment, the organic insulation layers 102 and 102b and the organic insulation layer 202 may contain a photosensitive resin composition. The photosensitive resin composition may contain the curable resin. Since the organic insulation layers 102 and 102b and the organic insulation layer 202 are formed of the photosensitive resin composition, in the electrode integration, production by means of a damascene process is enabled. Furthermore, in this case, since the same materials as those used in the steps of redistribution wiring and passivation that have already been put into practical use can be used, it is easy to put to practical use.

In the method for manufacturing a semiconductor device according to the present embodiment, the photosensitive resin composition preferably contains an alkali-soluble resin having a phenolic hydroxyl group, a compound that generates acid upon exposure to light, a thermal crosslinking agent, and an acrylic resin. In this case, the photosensitive resin composition can be cured at a low temperature, and the curing rate of the organic insulation layer can be efficiently increased. Furthermore, since adhesion can be improved and good thermal shock resistance can be obtained, the function as an insulation layer can be improved.

In the method for manufacturing a semiconductor device according to the present embodiment, the organic insulation layers 102 and 102b and the organic insulation layer 202 may be formed of the same type of resin material. In this case, in step (c) of heating at least one of the first semiconductor substrate 100 and the second semiconductor substrate 200, the first semiconductor substrate 100 may be heated at a first temperature, and the second semiconductor substrate 200 may be heated at a second temperature. The first temperature referred to here may be higher than the second temperature. In this case, the curing rates of the organic insulation layers 102 and 102b and the organic insulation layer 202 can be easily set to desired values.

Although the embodiments of the method for manufacturing a semiconductor device according to the present disclosure have been described in detail above, the present invention is not limited to the above-described embodiments, and can be applied to various embodiments or examples. For example, in the above description, the case where the present invention is applied to the CoW bonding in which the first semiconductor substrate 100 is bonded after being singulated into semiconductor chips 10 has been described, but the present invention may be applied to Wafer-to-Wafer (W2W) bonding in which the first semiconductor substrate 100 as a semiconductor wafer is bonded to the second semiconductor substrate 200 without being singulated.

Even in such a case, the desired bonding strength (shear strength) can be easily obtained.

### EXAMPLE

Hereinafter, the present invention will be described more specifically with reference to examples, but the present invention is not limited to examples.

### First Example

12-inch silicon wafers (substrate bodies 101 and 201) were prepared as wafers corresponding to the first semiconductor substrate 100 and the second semiconductor substrate 200 according to the above-described embodiment. The redistribution wiring portions 103 and 203 were formed on the silicon wafers. After an organic insulation material was applied onto the silicon wafers on which the redistribution wiring portions 103 and 203 were formed and spin coating was performed, heating was performed to volatilize the solvent in the application solution to form a film and organic insulation layers 102 and 202 having a thickness of 5 μm were formed. The organic insulation material used here was the following photosensitive resin composition. Thus, the first semiconductor substrate 100 and the second semiconductor substrate 200 were prepared.

### [Photosensitive Resin Composition]

100 g of the component (A), 15 g of the component (B), 15 g of the component (C), 10 g of the component (D), 120 g of ethyl lactate as a solvent, and 2 g of a 50% methanol solution of ureidopropyltriethoxysilane as a coupling agent were mixed, the mixture was subjected to pressure-filtration using a Teflon (registered trademark) filter having 3-μm pores, and a positive photosensitive resin composition of the first example was prepared.
Component (A): a 4-hydroxystyrene/methyl methacrylate copolymer (50/50 molar ratio) (weight-average molecular weight in terms of polystyrene=10000; manufactured by Maruzen Petrochemical Co., Ltd.; trade name “MARUKA LYNCUR CMM”)
Component (B): 1-naphthoquinone-2 diazide-5 sulfonic acid ester of 1,1-bis(4-hydroxyphenyl)-1-[4-{1-(4-hydroxyphenyl)-1-methylethyl}phenyl]ethane (esterification degree: about 90%; manufactured by AZ Electronic Materials; trade name “TPPA528”)
Component (C): hexakis(methoxymethyl) melamine (trade name “NICALAC MW-30HM” manufactured by SANWA CHEMICAL CO., LTD.; a compound represented by the following structural formula)

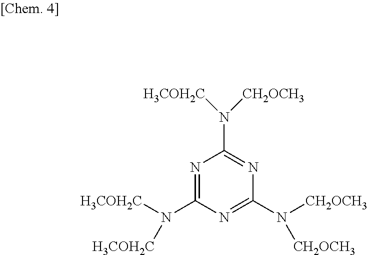

Component (D): acrylic resin

The acrylic resin as the component (D) was synthesized as follows.

Into a 500-ml three-necked flask equipped with a stirrer, a nitrogen inlet tube, and a thermometer, 75 g of toluene and 75 g of isopropanol (IPA) were weighed, and 85 g of butyl acrylate (BA), 24 g of lauryl acrylate (DDA), 14 g of acrylic acid (AA), and 7.9 g of 1,2,2,6,6-pentamethylpiperidin-4-yl methacrylate (trade name: FA-711 MM; manufactured by Resonac Corporation), which were separately weighed, were added as polymerizable monomers, along with 0.13 g of azobisisobutyronitrile (AIBN). While stirring at a stirring speed of about 270 rpm at room temperature, nitrogen gas was flowed at a flow rate of 400 ml/min for 30 minutes to remove dissolved oxygen. Thereafter, the inflow of the nitrogen gas was stopped, the flask was sealed, and the temperature was raised to 65° C. over about 25 minutes using a constant-temperature water bath. The polymerization reaction was performed while maintaining the same temperature for 14 hours to obtain an acrylic resin D. The polymerization ratio at this time was 98%. Furthermore, the weight-average molecular weight (Mw) of the acrylic resin D determined in terms of standard polystyrene by a GPC method was about 36,000.

Subsequently, the prepared first semiconductor substrate 100 and second semiconductor substrate 200 were disposed in the heating device H, and heated at a heating temperature (° C.) shown in Table 2 below for 30 minutes. Specifically, the first semiconductor substrate 100 (semiconductor chip) was heated to 200° C. such that the curing rate was 100%. On the other hand, the second semiconductor substrate (semiconductor wafer) heated to 120° C. had the curing rate of 0%.

Subsequently, the heat-cured first semiconductor substrate 100 was singulated by a dicer to obtain a plurality of semiconductor chips 10. The acquired semiconductor chips 10 were picked up by a chip bonder CB and mounted on a semiconductor wafer which is the second semiconductor substrate 200. The temperature at the time of bonding by the chip bonder CB was 230° C., the bonding pressure was 1.5 MPa, and the bonding time was 10 seconds. Thereafter, the bonded body S having the semiconductor chips 10 mounted on the second semiconductor substrate 200 was disposed in the heating device H, and reheating was performed. The reheating condition was 230° C. for 2 hours.

The shear strength of the bonded body S (semiconductor device 1) according to the first example subjected to reheating was measured based on the shear strength test method illustrated in FIG. 5. The evaluation of shear strength was defined as follows: 20 MPa or more was designated as “Evaluation S”, 10 MPa or more and less than 20 MPa as “Evaluation A”, 5 MPa or more and less than 10 MPa as “Evaluation B”, and less than 5 MPa as “Evaluation C”. Since the shear strength was preferably equal to or more than 5 MPa, “Evaluations S, A, and B” in shear strength were regarded as acceptable. The shear strength of the semiconductor device according to the first example was “Evaluation S”. Furthermore, resin delamination at the time of singulation into semiconductor chips was also evaluated, and a semiconductor chip without resin delamination was designated as “Evaluation A”, a semiconductor chip with partial resin delamination was designated as “Evaluation B”, and a semiconductor chip with severe resin delamination was designated as “Evaluation C”. The resin delamination of the semiconductor device according to the first example was “Evaluation A”.

### Second Example

In a second example, a semiconductor device according to the second example was produced under the same condition as that in the first example except that the bonding time was changed to 20 seconds, and the shear strength and resin delamination were evaluated. The shear strength of the semiconductor device according to the second example was “Evaluation S”. Furthermore, the resin delamination at the time of singulation into semiconductor chips was designated as “Evaluation A”.

### Third Example

In a third example, a semiconductor device was produced under the same condition as that in the first example except that the heating temperature of the second semiconductor substrate 200 in step (c) was increased to 140° C. to increase the curing rate of the second semiconductor substrate 200 to 50%, and the shear strength and resin delamination were evaluated. The shear strength of the semiconductor device according to the third example was designated as “Evaluation A”. Furthermore, the resin delamination at the time of singulation into semiconductor chips was designated as “Evaluation A”. It was confirmed that even when the second semiconductor substrate 200 was cured to some extent (curing rate: 50%), the shear strength was maintained at a high level of 10 MPa or more. However, from a comparison between the first example and the third example, it was confirmed that when the curing rate of the second semiconductor substrate 200 is increased, the shear strength between the organic insulation layers decreases.

### Fourth Example

In a fourth example, a semiconductor device was produced under the same condition as that in the first example except that the heating temperature of the first semiconductor substrate 100 in step (c) was decreased to 160° C. to decrease the curing rate of the first semiconductor substrate 100 (semiconductor chip 10) to 80%, and the shear strength and resin delamination were evaluated. The shear strength of the semiconductor device according to the fourth example was designated as “Evaluation A”. Furthermore, the resin delamination at the time of singulation into semiconductor chips was designated as “Evaluation A”. From the comparison between the first example and the fourth example, it was confirmed that when the curing rate of the organic insulation layer 102b of the first semiconductor substrate 100 (semiconductor chip 10) is increased (for example, the curing rate is equal to or more than 90%), the shear strength is remarkably improved.

### Fifth Example

In a fifth example, a semiconductor device was produced under the same condition as that in the fourth example except that the heating temperature of the second semiconductor substrate 200 in step (c) was increased to 160° C. to increase the curing rate of the second semiconductor substrate 200 to 80%, and the shear strength and resin delamination were evaluated. The shear strength of the semiconductor device according to the fifth example was designated as “Evaluation A”. Furthermore, the resin delamination at the time of singulation into semiconductor chips was designated as “Evaluation A”.

### Sixth Example

In a sixth example, a semiconductor device was produced under the same condition as that in the fifth example except that the heating temperature of the second semiconductor substrate 200 in step (c) was decreased to 140° C. to decrease the curing rate of the second semiconductor substrate 200 to 50%, and the shear strength and resin delamination were evaluated. The shear strength of the semiconductor device according to the sixth example was designated as “Evaluation B”. Furthermore, the resin delamination at the time of singulation into semiconductor chips was designated as “Evaluation A”.

### Seventh Example

In a seventh example, a semiconductor device was produced under the same condition as that in the first example except that the heating temperature of the first semiconductor substrate 100 in step (c) was decreased to 140° C. to decrease the curing rate of the first semiconductor substrate 100 (semiconductor chip 10) to 50%, and the heating temperature of the second semiconductor substrate 200 in step (c) was increased to 140° C. to increase the curing rate of the second semiconductor substrate 200 to 50%, and the shear strength and resin delamination were evaluated. The shear strength of the semiconductor device according to the seventh example was designated as “Evaluation A”. Furthermore, the resin delamination at the time of singulation into semiconductor chips was designated as “Evaluation B”. However, the semiconductor device 1 could be produced using a portion that is not delaminated.

### Eighth Example

In an eighth example, a semiconductor device was produced under the same condition as that in the seventh example except that the heating temperature of the second semiconductor substrate 200 in step (c) was decreased to 120° C. to decrease the curing rate of the second semiconductor substrate 200 to 0%, and the shear strength and resin delamination were evaluated. The shear strength of the semiconductor device according to the eighth example was designated as “Evaluation A”. Furthermore, the resin delamination at the time of singulation into semiconductor chips was designated as “Evaluation B”. However, the semiconductor device 1 could be produced using a portion that is not delaminated.

### Ninth Example

In a ninth example, a semiconductor device was produced under the same condition as that in the first example except that the following photosensitive resin composition was used as an organic insulation material in place of the photosensitive resin composition used in the first example, and the shear strength and resin delamination were evaluated. The shear strength of the semiconductor device according to the ninth example was designated as “Evaluation B”. Furthermore, the resin delamination at the time of singulation into semiconductor chips was designated as “Evaluation A”.

### [Photosensitive Resin Composition]

100 g of the component (A), 10 g of the component (B), 25 g of the component (C), and ethyl lactate as a solvent were mixed, the mixture was subjected to pressure-filtration using a polytetrafluoroethylene filter having 0.2 μm-pores, and a photosensitive resin composition was prepared.

### <Component (A)>

In order to synthesize the component (A), a bisimide phenol compound having a structure (al), a cresol compound having a structure (b1), 1,4-bis(methoxymethyl)benzene, 4,4-bis(methoxymethyl) biphenyl, and 37 mass % formaldehyde were prepared. An alkali-soluble resin having a structural unit (molar ratio) and a weight-average molecular weight (Mw) shown in Table 1 was synthesized. (c1) is a structure introduced by 1,4-bis(methoxymethyl)benzene, and (c2) is a structure introduced by formaldehyde.

TABLE 1

| Component (A) | | |
|---|---|---|
| a 1 | 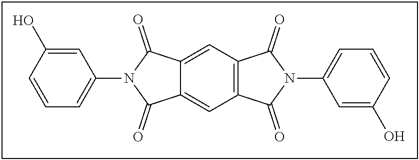 [SMILES: O=c1c2cc3c(=O)n(-c4cccc(O)c4)c(=O)c3cc2c(=O)n1-c1cccc(O)c1] | 10 |
| b 1 | 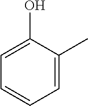 | 90 |
| c 1 | 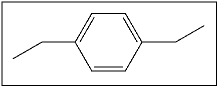 | 40 |
| c 2 | 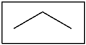 | 60 |
| | Mw | 18900 |

Into a 1 L three-necked flask equipped with a Dean-Stark device, N,N′-bis(3-hydroxyphenyl)-pyromellitimide, o-cresol, 1,4-bis(methoxymethyl)benzene, 37 mass % formaldehyde, γ-butyrolactone, and p-toluenesulfonic acid were added. The mixture was stirred and reacted at 180° C. for 6 hours. During this time, methanol, which is a byproduct of the reaction, was removed by liquid separation. The mixture was then cooled to 40° C. The reaction solution after cooling was added dropwise to 1 L of deionized water, and the precipitated resin was separated by filtration. The resin separated by filtration was vacuum-dried at 80° C. for 12 hours to obtain the alkali-soluble resin of the component (A).

The Mw of the component (A) can be measured by gel permeation chromatography (GPC), and can be derived by conversion using a calibration curve of standard polystyrene. By using a 5-sample set of standard polystyrene (PStQuick MP-H, PStQuick B; manufactured by Tosoh Corporation; trade name), the calibration curve was approximated by a cubic polynomial of the universal calibration curve in accordance with JIS K 7252-2 (2016). The GPC conditions are as follows.

### (GPC Conditions)

Detector: L-2490 RI (manufactured by Hitachi High-Tech Corporation)
Column: Gelpack GL-R440+R450+R400M (manufactured by Hitachi High-Tech Corporation)
Eluent: Tetrahydrofuran (THF)
Measurement temperature: 40° C.
Flow rate: 2.05 mL/min
Concentration: 5 mg/mL

### <Component (B)>

1-naphthoquinone-2 diazide-5 sulfonic acid ester of 1,1-bis(4-hydroxyphenyl)-1-[4-{1-(4-hydroxyphenyl)-1-methylethyl}phenyl]ethane (esterification degree: about 90%; manufactured by DAITO CHEMIX Co., Ltd.; trade name “PA28”)

### <Component (C)>

4,4′-[1-[4-[1-[4-hydroxy-3,5-bis(methoxymethyl)phenyl]-1-methylethyl]phenyl]ethylidene]bis[2,6-bis(methoxymethyl) phenol] (manufactured by Honshu Chemical Industry Co., Ltd.; trade name “HMOM-TPPA”)

### First Comparative Example

In a first comparative example, a semiconductor device was produced under the same condition as that in the first example except that the heating temperature of the first semiconductor substrate 100 in step (c) was decreased to 170° C. to decrease the curing rate of the first semiconductor substrate 100 (semiconductor chip 10) to 90%, and the heating temperature of the second semiconductor substrate 200 in step (c) was increased to 170° C. to increase the curing rate of the second semiconductor substrate 200 to 90%, and the shear strength and resin delamination were evaluated. That is, in the first comparative example, the curing rates of both were increased to 90%. The shear strength of the semiconductor device according to the first comparative example was designated as “Evaluation C”. Furthermore, the delamination at the time of singulation into semiconductor chips was designated as “Evaluation A”. The shear strength in the first comparative example was lower than 5 MPa as a reference.

### Second Comparative Example

In a second comparative example, a semiconductor device was produced under the same condition as that in the ninth example except that the heating temperature of the first semiconductor substrate 100 in step (c) was decreased to 170° C. to increase the curing rate of the first semiconductor substrate 100 (semiconductor chip 10) to 90% or more, and the heating temperature of the second semiconductor substrate 200 in step (c) was increased to 170° C. to increase the curing rate of the second semiconductor substrate 200 to 90% or more, and the shear strength and resin delamination were evaluated. That is, in the second comparative example, the curing rates of both were increased to 90% or more. The shear strength of the semiconductor device according to the second comparative example was designated as “Evaluation C”. Furthermore, the delamination at the time of singulation into semiconductor chips was designated as “Evaluation A”. The shear strength in the second comparative example was lower than 5 MPa as a reference.

TABLE 2

| | Semiconductor chip | | Semiconductor wafer | | |
|---|---|---|---|---|---|
| | | Curing | | Curing | Bonding |
| | Temperature | rate | Temperature | rate | time |
| | (° C.) | (%) | (° C.) | (%) | [seconds] |
| First example | 200 | 100 | 120 | 0 | 10 |
| Second example | 200 | 100 | 120 | 0 | 20 |
| Third example | 200 | 100 | 140 | 50 | 10 |
| Fourth example | 160 | 80 | 120 | 0 | 10 |
| Fifth example | 160 | 80 | 160 | 80 | 10 |
| Sixth example | 160 | 80 | 140 | 50 | 10 |
| Seventh example | 140 | 50 | 140 | 50 | 10 |
| Eighth example | 140 | 50 | 120 | 0 | 10 |
| Ninth example | 200 | 100 | 120 | 0 | 10 |
| First comparative | 170 | 90 | 170 | 90 | 10 |
| example | | | | | |
| Second | 170 | >90 | 170 | >90 | 10 |
| comparative | | | | | |
| example | | | | | |

Table 3 below summarizes the evaluation of the shear strength and the evaluation of the presence or absence of the resin delamination at the time of dicing in the first to ninth examples and the first and second comparative examples.

TABLE 3

| | Evaluation | Presence or absence of |
|---|---|---|
| | of shear | resin delamination at |
| | strength | time of dicing |
| First example | S | A |
| Second example | S | A |
| Third example | A | A |
| Fourth example | A | A |
| Fifth example | A | A |
| Sixth example | B | A |
| Seventh example | A | B |
| Eighth example | A | B |
| Ninth example | B | A |
| First comparative | C | A |
| example | | |
| Second comparative | C | A |
| example | | |

From Tables 2 and 3, it was confirmed that when the organic insulation layers 102b and 202 are bonded to each other, the bonding strength (shear strength) between the organic insulation layer 102b and the organic insulation layer 202 can be increased by increasing the curing rate of the organic insulation layer 102b to 30% or more and suppressing the curing rate of the organic insulation layer 202 to 85% or less. Specifically, it was confirmed that the bonding strength (shear strength) between the first semiconductor substrate 100 (semiconductor chip 10) and the second semiconductor substrate 200 is set to 5 MPa or more as a reference by setting each organic insulation layer to the above-described curing rate. Note that from the first and second comparative examples, it was found that when both the organic insulation layers were bonded at the curing rate of 90% or more, the bonding strength tended to decrease.

Furthermore, it was confirmed that when the organic insulation layers 102b and 202 are bonded to each other, the bonding strength (shear strength) between the organic insulation layer 102b and the organic insulation layer 202 can be increased to 20 MPa or more (or 30 MPa or more) by increasing the curing rate of the organic insulation layer 102b to 90% or more or 95% or more and suppressing the curing rate of the organic insulation layer 202 to 10% or less (including a 0% uncured state).

### REFERENCE SIGNS LIST

1 Semiconductor Device
10 Semiconductor Chip (First Semiconductor Substrate)
20 Semiconductor Wafer (Second Semiconductor Substrate)
100 First Semiconductor Substrate
101, 101b Substrate Body (First Substrate Body)
102, 102b Organic Insulation Layer (First Organic Insulation Layer)
103 Redistribution Wiring Portion (First Electrode)
200 Second Semiconductor Substrate
201 Substrate Body (Second Substrate Body)
202 Organic Insulation Layer (Second Organic Insulation Layer)
203 Redistribution Wiring Portion (Second Electrode)

1. A method for manufacturing a semiconductor device, the method comprising:
preparing a first semiconductor substrate including a first substrate body, a first organic insulation layer provided on a surface of the first substrate body, and at least one first electrode provided on the surface of the first substrate body;
preparing a second semiconductor substrate including a second substrate body, a second organic insulation layer provided on a surface of the second substrate body, and at least one second electrode provided on the surface of the second substrate body;
heating at least one of the first semiconductor substrate and the second semiconductor substrate to cure at least one of the first organic insulation layer and the second organic insulation layer by the heating; and
bonding the first organic insulation layer and the second organic insulation layer to each other and bonding the first electrode and the second electrode to each other, after the heating,
wherein the first organic insulation layer and the second organic insulation layer contain a curable resin and a thermal crosslinking agent,
wherein, after the heating, a curing rate of the first organic insulation layer to be subjected to the bonding is equal to or more than 30%, and after the heating, a curing rate of the second organic insulation layer to be subjected to the bonding is equal to or less than 85%.

2. The method for manufacturing a semiconductor device according to claim 1,
wherein the first semiconductor substrate is a semiconductor chip, and the second semiconductor substrate is a semiconductor wafer,
wherein, in the heating, the first semiconductor substrate is heated as a part of a large-sized semiconductor wafer,
wherein the large-sized semiconductor wafer is singulated to form the semiconductor chip after the heating and before the bonding, and, in the bonding, the first semiconductor substrate that is the semiconductor chip is bonded to the second semiconductor substrate that is the semiconductor wafer.

3. The method for manufacturing a semiconductor device according to claim 1,
wherein, in the heating, the first semiconductor substrate is heated such that the curing rate of the first organic insulation layer becomes equal to or more than 70%.

4. The method for manufacturing a semiconductor device according to claim 1,
wherein, in the heating, the first semiconductor substrate is heated such that the curing rate of the first organic insulation layer becomes equal to or more than 90%.

5. The method for manufacturing a semiconductor device according to any one of claims 1 to 4 claim 1,
wherein, in the heating, the second semiconductor substrate is heated such that the curing rate of the second organic insulation layer becomes equal to or less than 60%.

6. The method for manufacturing a semiconductor device according to claim 1,
wherein the curing rate of the second organic insulation layer is equal to or less than 10% when the first organic insulation layer and the second organic insulation layer are bonded to each other.

7. The method for manufacturing a semiconductor device according to claim 6,
wherein the second organic insulation layer is in an uncured state when the first organic insulation layer and the second organic insulation layer are bonded to each other.

8. The method for manufacturing a semiconductor device according to any one of claims 1 to 7 claim 1, further comprising reheating a bonded body of the first semiconductor substrate and the second semiconductor substrate after the bonding,
wherein a reheating temperature in the reheating the bonded body is higher than a heating temperature in the heating at least one of the first semiconductor substrate and the second semiconductor substrate.

9. The method for manufacturing a semiconductor device according to any one of claims 1 to 8 claim 1,
wherein the first organic insulation layer and the second organic insulation layer contain a photosensitive resin composition, and the photosensitive resin composition contains the curable resin.

10. The method for manufacturing a semiconductor device according to claim 9,
wherein the photosensitive resin composition contains an alkali-soluble resin having a phenolic hydroxyl group, a compound that generates acid upon exposure to light, the thermal crosslinking agent, and an acrylic resin.

11. The method for manufacturing a semiconductor device according to claim 1,
wherein the first organic insulation layer and the second organic insulation layer contain a polyimide resin.

12. The method for manufacturing a semiconductor device according to claim 1,
wherein the first organic insulation layer and the second organic insulation layer are formed of the same type of resin material, and
wherein the heating at least one of the first semiconductor substrate and the second semiconductor substrate includes heating the first semiconductor substrate at a first temperature and heating the second semiconductor substrate at a second temperature, the first temperature being higher than the second temperature.
